(19) United States
(12) Patent Application Publication
(10) Pub. No.: US 2017/0110580 A1
(43) Pub. Date: Apr. 20, 2017

(54) COMS STRUCTURE AND FABRICATION METHOD THEREOF

(71) Applicant: Zing Semiconductor Corporation, Shanghai (CN)

(72) Inventors: Deyuan Xiao, Shanghai (CN); Richard R. Chang, Shanghai (CN)

(21) Appl. No.: 15/004,245

(22) Filed: Jan. 22, 2016

(30) Foreign Application Priority Data
Oct. 20, 2015 (CN) 201510683929.3

(51) Int. Cl. H01L 29/78; H01L 21/306; H01L 21/3065; H01L 21/8238; H01L 27/092

(52) U.S. Cl. CPC H01L 29/7848; H01L 21/823814; H01L 21/823878; H01L 27/0922; H01L 21/3065; H01L 21/30604

(57) ABSTRACT

Present embodiments provide for a CMOS structure and a fabrication method thereof. While the source-drain epitaxial material formed in each of the PMOS device region and the NMOS device region, deuterium gas is used as the carrier gas to store the deuterium atoms in the interstice of the source-drain epitaxial material as an impurity. Since the source-drain epitaxial material is used as a source-drain, which is quite near the gate, the deuterium atoms can diffuse out from the source-drain epitaxial material during the process of forming the gate dielectric layer and covalently bound to the dangling bonds at the interface between the gate dielectric layer and the substrate, so as to obtain more stable structure, avoid penetration of the carriers, and eliminate hot carrier effects, such that performance and resilience of the device are increased.

### INCORPORATION BY REFERENCE

This application claims priority from China Patent Application No. 201510683929.3, filed on Oct. 20, 2015, the contents of which are hereby incorporated by reference in their entirety for all purposes.

### TECHNICAL FIELD

The present disclosure relates to a semiconductor manufacturing technology, and particularly, relates to a CMOS structure and fabrication method thereof.

### BACKGROUND

The metal-oxide-semiconductor (MOS) transistor is one of the most important active components in the integrated circuit, in which CMOS structure composed of complementary NMOS transistor and PMOS transistor is the component unit of deep sub-micron ultra large scale integrated circuit. For raising carrier mobility of MOS transistor, introducing stress in the channel region by changing the crystal structure of the channel region semiconductor substrate is well-known technology. The stress-introducing techniques in the prior art usually include: source and drain epitaxial silicon-germanium technique, stress etching stop layer technique, stress memorization technique, stress proximity technique and so on. Since the stress produced from one stress-introducing technique is limited, for raising the stress of the channel region, some of stress-introducing techniques are usually applied at the same time to produce stress in the channel region of MOS transistor.

In the fabrication process of the semiconductor device, the stress could change energy band gap and carrier mobility of semiconductor material to improve the performance of the MOS device. Therefore, the technique of increasing stress for raising the performance of the MOS device has become increasingly popular method. The increasing of carrier mobility could raise drive current, such that the performance of CMOS device is raised significantly. For example, embedded silicon germanium technologies could provide compressive stress to the channel region in PMOS transistor, such that the whole carrier mobility is increased to raise the performance of PMOS transistor.

However, there are dangling bands at the interface layers of different thin films in the present CMOS device, especially at the gate dielectric layer and the channel region, in which the dangling bonds could remove charge carriers or add unwanted charge carriers in the device. While dangling bonds occur primarily at surface or interface in the device, they also occur at vacancies, micro pores, and also to be associated with impurities. Too many dangling bonds usually introduce larger leakage current of the substrate to affect the overall performance of the device.

### SUMMARY

Aspects of the present disclosure may provide a CMOS structure and a fabrication method thereof.

In an exemplary embodiment, the fabrication method of the CMOS structure comprises the steps of: providing a substrate, wherein the substrate includes a PMOS device region and a NMOS device region, in which the PMOS device region and the NMOS device region are isolated by a shallow trench isolation structure; forming a gate, a sidewall, a gate dielectric layer and a source-drain trench in each of the PMOS device region and the NMOS device region, wherein in each of the PMOS device region and the NMOS device region, the gate dielectric layer is disposed on the substrate, the gate is disposed on the gate dielectric layer, the sidewall is disposed at each of the two sides of the gate, and the source-drain trench is disposed in each of the substrate near the two sides of the gate; and forming a source-drain epitaxial material in each of the source-drain trench of the PMOS device region and the source-drain trench of the NMOS device region, wherein a carrier gas including deuterium is used during forming of the source-drain epitaxial material.

In an aspect of the present disclosure, the source-drain trench in the PMOS device region is in Sigma (Σ) shape.

In an aspect of the present disclosure, the source-drain trench in the PMOS device region is formed by dry etching.

In an aspect of the present disclosure, the source-drain trench in the PMOS device region is formed by wet etching.

In an aspect of the present disclosure, the etching solution applied in the wet etching is a mixed solution of ammonia (NH₃) and water (H₂O), a solution of potassium hydroxide (KOH), or a solution of tetramethylazanium hydroxide (TMAH).

In an aspect of the present disclosure, the operating temperature of the wet etching is between 20 and 100 degrees Celsius (° C.), and the operating time of the wet etching is between 30 and 400 seconds (s).

In an aspect of the present disclosure, the source-drain epitaxial material formed in the source-drain trench in the PMOS device region is silicon-germanium (SiGe).

In an aspect of the present disclosure, the reactant gas for forming SiGe is a mixed gas of germane (GeH₄), hydrogen (H₂) and more than one of silane (SiH₄), disilane (Si₂H₆), dichlorosilane (SiH₂Cl₂), trichlorosilane (SiHCl₃), tetrachlorosilane (SiCl₄) and tetramethylsilane (Si(CH₃)₄).

In an aspect of the present disclosure, the gas flow of GeH₄ or one of SiH₄, Si₂H₆, SiH₂Cl₂, SiHCl₃, SiCl₄ or Si(CH₃)₄ is between 10 sccm and 800 sccm.

In an aspect of the present disclosure, the source-drain trench in the NMOS device region is in U shape.

In an aspect of the present disclosure, the source-drain trench in the NMOS device region is formed by wet etching.

In an aspect of the present disclosure, the etching gas applied in the dry etching is a mixed gas of chlorine (Cl₂) gas and argon (Ar) gas.

In an aspect of the present disclosure, the source-drain trench in the NMOS device region is formed by wet etching.

In an aspect of the present disclosure, the source-drain epitaxial material formed in the source-drain trench in the NMOS device region is silicon carbide (SiC).

In an aspect of the present disclosure, the reactant gas for forming SiC is the mixed gas of silane (SiH₄), hydrogen (H₂), and one of propane (C₃H₈) and methane (CH₄).

In an aspect of the present disclosure, the carrier gas for forming the source-drain epitaxial material is deuterium gas, the mixed gas of deuterium gas and hydrogen (H₂) gas, or the mixed gas of deuterium gas, hydrogen (H₂) gas and argon (Ar) gas.

In an aspect of the present disclosure, a selective etching gas for forming the source-drain epitaxial material is hydrogen chloride (HCl) gas or chlorine (Cl₂) gas.

In an aspect of the present disclosure, the gas flow of the selective etching gas is between 10 sccm and 800 sccm.

In an aspect of the present disclosure, the operating temperature of forming the source-drain epitaxial material is between 600 Celsius and 1200 degrees Celsius (° C.).

In an aspect of the present disclosure, the reactant pressure of forming the source-drain epitaxial material is between 1 Torr and 500 Torr.

In an exemplary embodiment, a CMOS structure comprises: the PMOS device region and the NMOS device region, wherein the gate, the sidewall, the gate dielectric layer and the source-drain trench are formed in each of the PMOS device region and the NMOS device region, in which the gate dielectric layer is formed on the substrate, the gate is formed on the gate dielectric layer, the sidewall is formed on each of the two sides of the gate, the source-drain epitaxial material formed in the source-drain trench is disposed in each of the substrate near the two sides of the gate, and the deuterium atoms are introduced at the interface between the gate dielectric layer and the substrate.

Aforesaid exemplary embodiments are not limited and could be selectively incorporated in other embodiments described herein.

### BRIEF DESCRIPTION OF THE DRAWINGS

Exemplary embodiments will be more readily understood from the following detailed description when read in conjunction with the appended drawing, in which:

FIG. 1 is a flow chart of a fabrication method of a CMOS structure according to one embodiment of the present disclosure; and

FIG. 2 is a cross-sectional view showing the CMOS structure according to one embodiment of the present disclosure.

### DETAILED DESCRIPTION

The following detailed description in conjunction with the drawings of the CMOS structure and fabrication method thereof of the present invention represents the preferred embodiments. It should be understood that the skilled in the art can modify the present invention described herein to achieve advantageous effect of the present invention. Therefore, the following description should be understood as well known for the skilled in the art, but should not be considered as a limitation to the present invention.

For clarity and brevity, not all features of the actual embodiments are described in the specification. In the following description, a detailed description of known functions and configurations incorporated herein will be omitted when it may obscure the subject matter with unnecessary details. However, it shall be understood that decisions specific to embodiments have to be made in a procedure of developing such an actual embodiment to achieve the specific object of the developer, for example, complying with limited conditions relative to system and commerce, and those limited conditions may change in different embodiments. In addition, it shall be understood that although the developing working may be complex and time consuming, such a developing working is only routine for those skilled in the art benefit from the disclosure of the disclosure.

Reference will now be made in detail to several views of the invention that are illustrated in the accompanying drawings. In accordance with the following specification and claims, the advantages and features of the present invention are clearer. It should be noted that the drawings are in simplified form and are not to precise scale for purposes of convenience and clarity only to describe the embodiments of the present invention.

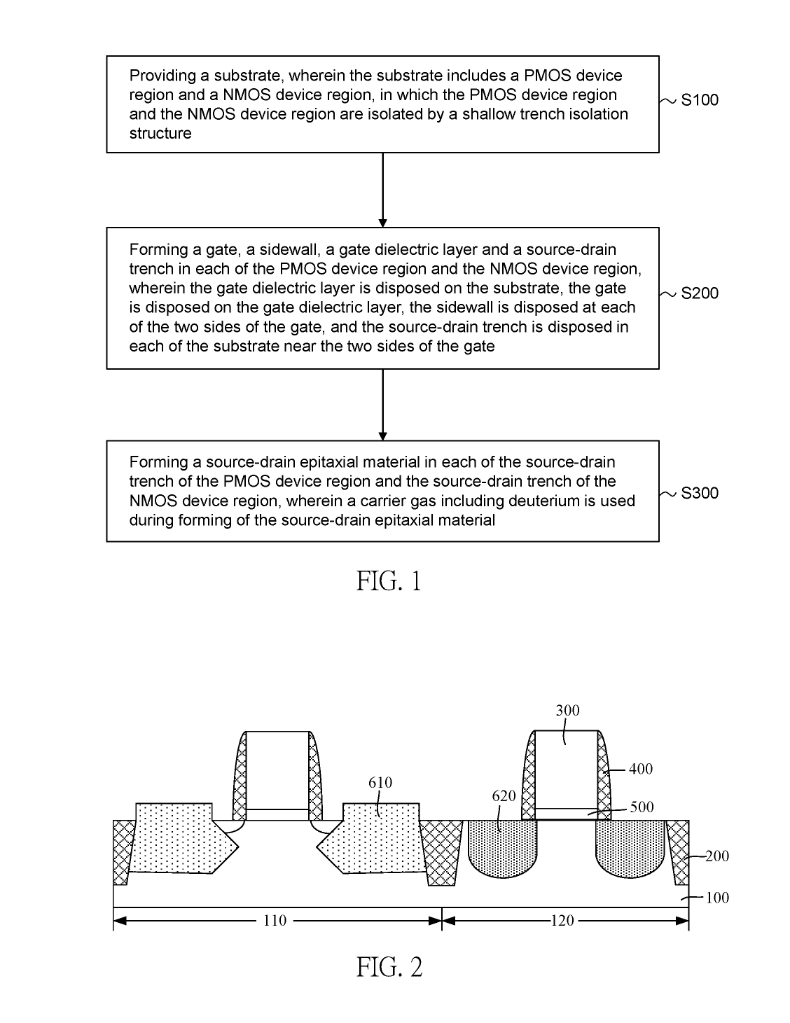

Referring to FIG. 1, a fabrication method of CMOS structure is provided according to the present embodiment, in which the method comprises:

S100: Providing a substrate, wherein the substrate includes a PMOS device region and a NMOS device region, in which the PMOS device region and the NMOS device region are isolated by a shallow trench isolation structure.

S200: Forming a gate, a sidewall, a gate dielectric layer and a source-drain trench in each of the PMOS device region and the NMOS device region, wherein the gate dielectric layer is disposed on the substrate, the gate is disposed on the gate dielectric layer, the sidewall is disposed on each of the two sides of the gate, and the source-drain trench is disposed in each of the substrate near the two sides of the gate.

S300: Forming a source-drain epitaxial material in each of the source-drain trench of the PMOS device region and the source-drain trench of the NMOS device region, wherein a carrier gas including deuterium gas is used during the process of forming the source-drain epitaxial material.

Specifically, referring to FIG. 2, the substrate 100 includes the PMOS device region 110 and the NMOS device region 120, in which the PMOS device region 110 and the NMOS device region 120 are isolated by a shallow trench isolation structure 200, wherein the shallow trench isolation structure 200 may be silicon dioxide (SiO₂).

The gate 300, the sidewall 400, the gate dielectric layer 500 and the source-drain trench are formed in each of the PMOS device region 110 and the NMOS device region 120, wherein the gate dielectric layer 500 is disposed on the substrate 100, the gate 300 is disposed on the gate dielectric layer 500, the sidewall 400 is disposed on each of the two sides of the gate 300, and the source-drain trench is disposed in each of the substrate 100 near the two sides of the gate 300.

The source-drain trench in the PMOS device region 110 is in Sigma (Σ) shape, which can be formed by dry etching or wet etching. For example, when the wet etching is applied, the etching solution may consist of a mixed solution of ammonia (NH₃) and water (H₂O), a solution of potassium hydroxide (KOH), or a solution of tetramethylazanium hydroxide (TMAH), the operating temperature is between 20 and 100 degrees Celsius (° C.), such as 50° C., and the operating time is between 30 and 400 seconds (s), such as 200 s.

The source-drain trench in the NMOS device region 120 is in U shape, which can be formed by dry etching or wet etching. For example, when the dry etching is applied, the etching gas may consist of a mixed gas of chlorine (Cl₂) gas and argon (Ar) gas.

A silicon-germanium (SiGe) 610 is formed in the source-drain trench in the PMOS device region 110 as a source-drain epitaxial material, in which the reactant gas for forming SiGe 610 is the mixed gas of germane (GeH₄) and more than one of silane (SiH₄), disilane (Si₂H₆), dichlorosilane (SiH₂Cl₂), trichlorosilane (SiHCl₃), tetrachlorosilane (SiCl₄) and tetramethylsilane (Si(CH₃)₄). The gas flow of GeH₄ or one of SiH₄, Si₂H₆, SiH₂Cl₂, SiHCl₃, SiCl₄ or Si(CH₃)₄ is between 10 sccm and 800 sccm, such as 400 sccm. A silicon carbide (SiC) 620 is formed in the source-drain trench in the NMOS device region 120 as a source-drain epitaxial material, in which the reactant gas for forming SiC 620 is the mixed gas of SiH₄, hydrogen (H₂), and one of propane (C₃H₈) and methane (CH₄).

Before forming the source-drain epitaxial material in the PMOS device region 110, a hard mask (HM) layer could be formed on the NMOS device region 120 to shield the NMOS device region 120. After forming the source-drain epitaxial material in the PMOS device region 110, the HM layer on the NMOS device region 120 is removed and the HM layer could be formed on the PMOS device region 110 to shield the PMOS device region 110 before SiC is formed in the NMOS device region 120.

Moreover, when the source-drain epitaxial material is formed, the carrier gas includes deuterium gas, such as pure deuterium gas, the mixed gas of deuterium gas and H₂ gas, or the mixed gas of deuterium gas, H₂ gas and Ar gas.

Besides above mentioned carrier gas, a selective etching gas, such as hydrogen chloride (HCl) gas or Cl₂ gas could also be applied. The selective etching gas may be fed when the reactant gas is reacted, or after a period of time of reaction according to specific technological requirements. The selective etching gas could etch redundant source-drain epitaxial material, and that is favorable to fill the source-drain epitaxial material in the trench.

The operating temperature of forming the source-drain epitaxial material is between 600° C. and 1200° C., such as 1000° C. The reactant pressure of forming the source-drain epitaxial material is between 1 Torr and 500 Torr, such as 300 Torr. The specific technological parameter could be selected according to different technological environment, but not limited to above mention range.

According to another aspect of the present embodiment, a CMOS structure is provided. As shown in FIG. 2, the CMOS structure is fabricated by the above mentioned fabrication method of CMOS structure. The CMOS structure comprises: the substrate comprising the PMOS device region 110 and the NMOS device region 120, in which the gate 300, the sidewall 400, the gate dielectric layer 500 and the source-drain trench are formed in each of the PMOS device region 110 and the NMOS device region 120, and the gate dielectric layer 500 is formed on the substrate 100, the gate 300 is formed on the gate dielectric layer 500, the sidewall 400 is formed on each of the two sides of the gate 300, the source-drain epitaxial material formed in the source-drain trench is disposed in each of the substrate near the two sides of the gate 300, and the deuterium atoms are introduced at the interface between the gate dielectric layer 500 and the substrate 100.

Above all, the CMOS structure and the fabrication method thereof according to the embodiment in the present invention have following characteristics: While the source-drain epitaxial material formed in each of the PMOS device region and the NMOS device region, deuterium gas is used as the carrier gas to store the deuterium atoms in the interstice of the source-drain epitaxial material as an impurity. Since the source-drain epitaxial material is used as a source-drain, which is quite near the gate, the deuterium atoms can diffuse out from the source-drain epitaxial material during the process of forming the gate dielectric layer and covalently bound to the dangling bonds at the interface between the gate dielectric layer and the substrate, so as to obtain more stable structure, avoid penetration of the carriers, and eliminate hot carrier effects, such that performance and resilience of the device are increased.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

1. A fabrication method of a CMOS structure, comprising the steps of:
providing a substrate, wherein the substrate includes a PMOS device region and a NMOS device region, in which the PMOS device region and the NMOS device region are isolated by a shallow trench isolation structure;
forming a gate, a sidewall, a gate dielectric layer and a source-drain trench in each of the PMOS device region and the NMOS device region, wherein in each of the PMOS device region and the NMOS device region, the gate dielectric layer is disposed on the substrate, the gate is disposed on the gate dielectric layer, the sidewall is disposed at each of the two sides of the gate, and the source-drain trench is disposed in each of the substrate near the two sides of the gate; and
forming a source-drain epitaxial material in each of the source-drain trench of the PMOS device region and the source-drain trench of the NMOS device region, wherein a carrier gas including deuterium is used during forming of the source-drain epitaxial material,
wherein the source-drain trench in the PMOS device region is in Sigma (Σ) shape.

2. (canceled)

3. The method according to claim 1, wherein the source-drain trench in the PMOS device region is formed by dry etching.

4. The method according to claim 1, wherein the source-drain trench in the PMOS device region is formed by wet etching.

5. The method according to claim 4, wherein the etching solution applied in the wet etching is a mixed solution of ammonia (NH₃) and water (H₂O), a solution of potassium hydroxide (KOH), or a solution of tetramethylazanium hydroxide (TMAH).

6. The method according to claim 4, wherein the operating temperature of the wet etching is between 20 and 100 degrees Celsius (° C.), and the operating time of the wet etching is between 30 and 400 seconds (s).

7. The method according to claim 1, wherein the source-drain epitaxial material formed in the source-drain trench in the PMOS device region is silicon-germanium (SiGe).

8. The method according to claim 7, wherein the SiGe is formed by using a reactant gas, which is a mixed gas of germane (GeH₄) and more than one of silane (SiH₄), disilane (Si₂H₆), dichlorosilane (SiH₂Cl₂), trichlorosilane (SiHCl₃), tetrachlorosilane (SiCl₄) and tetramethylsilane (Si(CH₃)₄).

9. The method according to claim 8, wherein the gas flow of GeH₄ or one of SiH₄, Si₂H₆, SiH₂Cl₂, SiHCl₃, SiCl₄ or Si(CH₃)₄ is between 10 sccm and 800 sccm.

10. The method according to claim 1, wherein the source-drain trench in the NMOS device region is in U shape.

11. The method according to claim 10, wherein the source-drain trench in the NMOS device region is formed by dry etching.

12. The method according to claim 11, wherein the dry etching is conducted by applying an etching gas, which is a mixed gas of chlorine (Cl₂) gas and argon (Ar) gas.

13. The method according to claim 1, wherein the source-drain trench in the NMOS device region is formed by wet etching.

14. The method according to claim 1, wherein the source-drain epitaxial material formed in the source-drain trench in the NMOS device region is silicon carbide (SiC).

15. The method according to claim 14, wherein the SiC is formed by using a reactant gas, which is a mixed gas of silane (SiH₄), hydrogen (H₂), and one of propane (C₃H₈) and methane (CH₄).

16. The method according to claim 1, wherein the carrier gas for forming the source-drain epitaxial material is deuterium gas, the mixed gas of deuterium gas and hydrogen (H₂) gas, or the mixed gas of deuterium gas, hydrogen (H₂) gas and argon (Ar) gas.

17. The method according to claim 1, wherein a selective etching gas for forming the source-drain epitaxial material is hydrogen chloride (HCl) gas or chlorine (Cl₂) gas.

18. The method according to claim 17, wherein the gas flow of the selective etching gas is between 10 sccm and 800 sccm.

19. The method according to claim 1, wherein the source-drain epitaxial material is formed at an operating temperature of between 600 Celsius and 1200 degrees Celsius (° C.).

20. The method according to claim 1, wherein the source-drain epitaxial material is formed under a reactant pressure of between 1 Torr and 500 Torr.

21. A CMOS structure fabricated by the method of claim 1, comprising:
the PMOS device region and the NMOS device region, wherein the gate, the sidewall, the gate dielectric layer and the source-drain trench are formed in each of the PMOS device region and the NMOS device region, in which the gate dielectric layer is formed on the substrate, the gate is formed on the gate dielectric layer, the sidewall is formed on each of the two sides of the gate, the source-drain epitaxial material formed in the source-drain trench is disposed in each of the substrate near the two sides of the gate, and the deuterium atoms are introduced at the interface between the gate dielectric layer and the substrate, and
wherein the source-drain trench in the PMOS device region is in Sigma (Σ) shape.
